(19) United States
(12) Patent Application Publication
(10) Pub. No.: US 2018/0062366 A1
(43) Pub. Date: Mar. 1, 2018

(54) Enclosed Housing for Alarm System Electrical Equipment

(71) Applicant: John Bandre, Ethelsville, AL (US)

(72) Inventor: John Bandre, Ethelsville, AL (US)

(21) Appl. No.: 15/677,430

(22) Filed: Aug. 15, 2017

Related U.S. Application Data
(60) Provisional application No. 62/379,062, filed on Aug. 24, 2016.

(51) Int. Cl. H02G 3/14; H02G 3/12; H05K 5/02; H01R 13/502

(52) U.S. Cl. CPC H02G 3/14; H01R 13/502; H05K 5/0217; H02G 3/126

(57) ABSTRACT

A recessed enclosure for housing alarm system electrical equipment. The recessed enclosure includes a rear wall and peripheral sidewalls which form an enclosure. At least one flange extends orthogonally outward from the sidewalls with apertures for securing the housing to a wall stud or other suitable area for recessed housing. An inner lip extends orthogonally inward from the peripheral sidewalls. A second peripheral sidewall extends forward from substantially the same position as the first and terminates in a front facing edge. A covering is disposed inside the second peripheral sidewall and hingedly connected to the inner lip. Knock-out sections for receiving electrical equipment are situated along the rear and sidewalls. Tie-ins for managing electrical wiring are also disposed along an interior of the rear wall and sidewalls. A frame fits over an outer edge of the sidewall and rests flush with the wall and covering.

### CROSS REFERENCE TO RELATED APPLICATIONS

This application claims the benefit of U.S. Provisional Application No. 62/379,062 filed on Aug. 24, 2016. The above identified patent application is herein incorporated by reference in its entirety to provide continuity of disclosure.

### BACKGROUND OF THE INVENTION

The present invention relates to enclosed housings for alarm system electrical equipment. More specifically, the present invention provides a recessed enclosure with knock out sections and wiring tie-ins for housing electrical equipment inside of walls.

Alarm systems require extensive wiring and dedicated electrical systems. These electrical systems and components need to be housed in an enclosed area away from the elements. The electrical system requires the use of circuit boards as well as 110 VAC outlet connections and other components which vary depending on the size and sophistication of the alarm system.

Currently, alarm system electrical equipment is housed in exposed enclosures which pose numerous problems. These enclosures protrude from the wall and create a hazard for workers during construction. During installation, wiring is often times left hanging out of the exposed enclosures which creates a problem for workers installing drywall or siding. These protrusions create an eyesore and also can lead to damage of the enclosure or electrical components. In order to address these concerns, the present invention provides a recessed enclosure with knock-out sections and wiring tie-ins to be mounted between wall studs to remain hidden and flush with the wall surface.

### SUMMARY OF THE INVENTION

In view of the foregoing disadvantages inherent in the known types of alarm system electrical housing now present in the prior art, the present invention provides a recessed housing enclosure for alarm system electrical equipment wherein the same can be utilized for providing convenience for the user when installing alarm systems of differing sizes and complexities inside of a wall.

It is therefore an object of the present invention to provide a new housing for alarm system electrical equipment that has all of the advantages of the prior art and none of the disadvantages.

It is another object of the present invention to provide a housing for alarm system electrical equipment comprising an enclosure defining an interior volume with a hingedly attached planar covering wherein at least one flange extends orthogonally from the sidewall and is utilized to secure the enclosure to a wall support, wherein the planar covering and frame rest flush with a wall surface.

It is another object of the present invention to provide a housing for alarm system electrical equipment comprising a space configured to receive an electrical circuit board is disposed therein.

It is another object of the present invention to provide a housing for alarm system electrical equipment wherein a plurality of planar flanges extend orthogonally from the peripheral sidewalls.

Yet another object of the present invention is to provide a housing for alarm system electrical equipment wherein apertures for receiving fasteners are disposed at regular intervals along a perimeter of the outer flanges.

Another object of the present invention is to provide a housing for alarm system electrical equipment wherein knock-out sections are disposed along the rear wall and the peripheral sidewalls, the knock-out sections configured to be removed from the housing, such that electrical components can be received therethrough.

Another object of the present invention is to provide a housing for alarm system electrical equipment wherein tie-ins for electrical wiring management are disposed along the interior of the rear wall and the peripheral sidewalls.

Another object of the present invention is to provide a housing for alarm system electrical equipment wherein a locking mechanism is attached to the planar covering for securing the enclosure.

Other objects, features and advantages of the present invention will become apparent from the following detailed description taken in conjunction with the accompanying drawings.

### BRIEF DESCRIPTION OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows perspective view of an embodiment of the housing for alarm system electrical equipment with planar covering in an open position.

FIG. 2 shows a perspective view of an embodiment of the housing for alarm system electrical equipment disposed in a wall with frame flush with the wall and planar covering in a closed position.

FIG. 3 shows a rear view of the planar frame of an embodiment of the housing for alarm system electrical equipment.

FIG. 4 shows a perspective view of an embodiment of the housing for alarm system electrical equipment in use between two wall studs with planar covering in an opened position.

### DETAILED DESCRIPTION OF THE INVENTION

Reference is made herein to the attached drawings. Like reference numerals are used throughout the drawings to depict like or similar elements of the housing for alarm system electrical equipment. For the purposes of presenting a brief and clear description of the present invention, the preferred embodiment will be discussed as used for a recessed enclosure of electrical devices and wiring. The figures are intended for representative purposes only and should not be considered to be limiting in any respect.

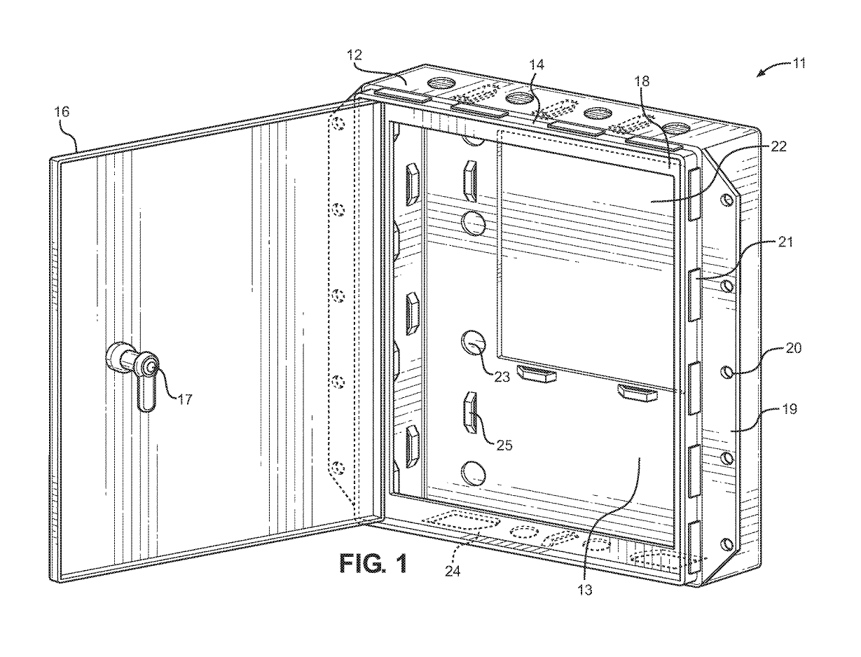

Referring now to FIG. 1, there is shown a perspective view of an embodiment of the housing for alarm system electrical equipment with planar covering in an open position. The housing for alarm system electrical equipment 11 comprises a rear wall 13 having a peripheral sidewall 12 extending orthogonally from the edges of the rear wall 11 and connecting to define an enclosure with front facing opening. An inner lip 18 extends orthogonally inward from the peripheral sidewalls 12 and connects over the interior enclosure.

At least one planar flange 19 extends orthogonally outward from the peripheral sidewall 12. The planar flange 19 comprises apertures 20 thereon, the apertures 20 disposed at regular intervals and configured to receive fasteners therethrough, such that the housing for alarm system electrical equipment 11 is removably affixed to a wall stud or any other suitable surface. In the illustrated embodiment, a pair of opposing planar flanges 19 are disposed on opposing peripheral sidewalls 12, such that the housing 11 can be removably affixed to a pair of support surfaces on either side of the housing 11, such as a pair of wall studs.

The rear wall 13 and peripheral sidewall 12 have perforated knock-out sections 23 and 24 of various sizes that can be removed to receive electrical equipment and wiring therethrough. In the illustrated embodiment, the perforated knock-out sections 23 and 24 comprise a circular cross-section and a rectangular cross-section, however in alternate embodiments, the perforated knock-out sections 23, 24 comprise other cross-sectional shapes, such as square, or polygonal. The rear wall 13 further comprises a space 22 thereon, the space 22 configured to receive an electrical circuit board thereon. A plurality of tie-ins 25 are disposed along the rear wall 13 and peripheral sidewall 12 to accept and manage electrical wiring within the enclosure. In the illustrated embodiment, the tie-ins 25 comprise a series of planar elements, defining an opening thereunder, the opening configured to receive electrical wiring therethrough.

A second enclosure 14 extends orthogonally outward from the inner lip 18 in substantially the same positon as the peripheral sidewall 12 and terminating with an outer edge facing the opening. Slotted receiving tabs 21 are placed at regular intervals along the outer perimeter of the second enclosure 14. A planar covering 16 fits within the second enclosure 14 and is hingedly affixed to the inner lip 18. The planar covering 16 is configured to move between an open position and a closed position, wherein the closed position comprises the planar covering 16 resting flush against the surface of the inner lip 18, thereby creating an enclosed interior volume with the rear wall 13 and peripheral sidewall 12. In the illustrated embodiment, the planar covering 16 further comprises a locking mechanism 17 configured to retain the planar covering 16 in the closed position when the locking mechanism 17 is actuated, such as through operation of a key.

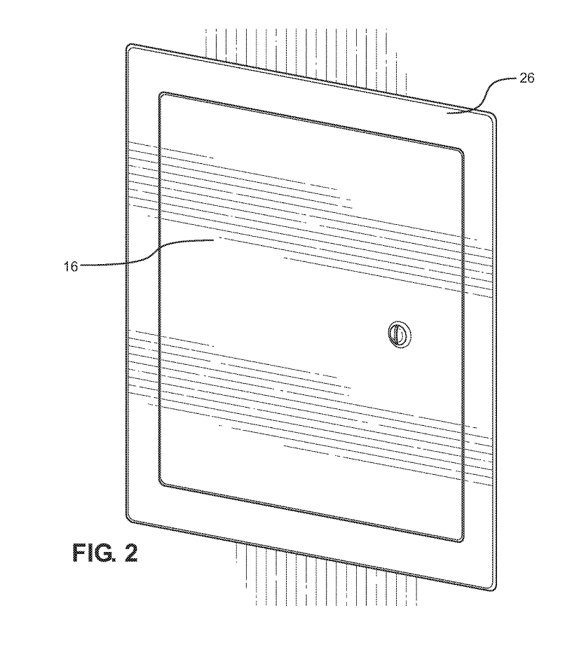

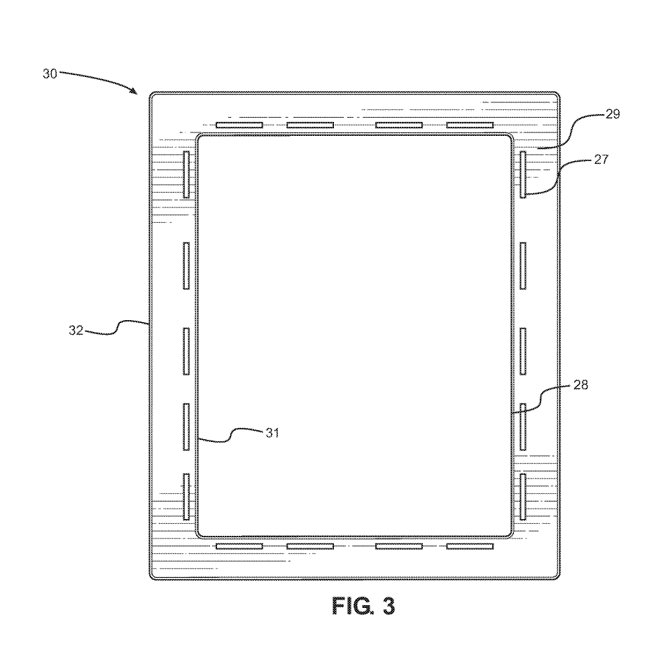

Referring now to FIGS. 2 and 3, there is shown a perspective view of an embodiment of the housing for alarm system electrical equipment in use with outer frame flush with the wall and planar covering in a closed position and a rear view of the outer frame for an embodiment of the housing for alarm system electrical equipment, respectively. The outer frame 30 comprises a front surface 26, a rear surface 29, an inner perimeter 31 and an outer perimeter 32. A frame lip 28 extends orthogonally away from the rear surface 29 at the inner perimeter 31. In an alternative embodiment, the outer perimeter 32 tapers down from the front surface 26 toward the rear surface 29.

In the illustrated embodiment, a plurality of tabs 27 are disposed along the outer frame 30 at regular intervals. The frame lip 28 is configured to fits within the second enclosure 14, such that the frame lip 28 rests flush against the inner lip 18, wherein the slots 27 receive the tabs therein. In the illustrated embodiment of FIG. 2, the outer frame 30 is configured to removably secure to the housing such that the front surface 26 rests flush with the planar covering 16 while the rear surface 29 rests flush against a wall or other surface.

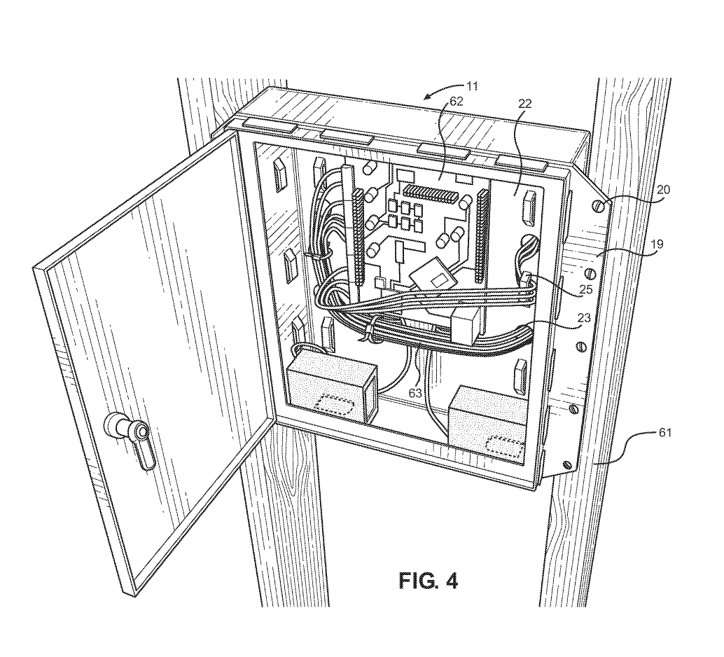

Referring now to FIG. 4, there is shown a perspective view of an embodiment of the housing for alarm system electrical equipment in use between two wall studs with planar covering in an opened position. In the illustrated embodiment, the housing 11 is mounted onto a pair of opposing wall studs 61. The housing 11 is removably secured thereto via fasteners inserted through the apertures 20 of the planar flange 19. In the illustrated embodiment, a plurality of wires 63 are threaded through the tie-ins 25 and inserted through the openings created by removing the perforated knock-out sections 23 from the housing 11. In this way, the wires 63 are constrained, such that the wires 63 do not interfere with the operation of the electronics. A circuit control board 62 is removably secured within the space 22, such that interior space is maximized.

It is therefore submitted that the instant invention has been shown and described in various embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1) A housing for alarm system electrical equipment, comprising:
a planar rear wall;
peripheral sidewalls extending orthogonally from the edges of the rear wall and joined together, wherein an enclosure with an open front face is defined;
an inner lip extending orthogonally inward over the interior volume and connected from the peripheral side walls;
at least one planar flange extending orthogonally outward from the peripheral side walls;
a second peripheral sidewall enclosure extending forward from the first edge in substantially the same position as the first peripheral sidewall enclosure, wherein tabs are disposed at regular intervals along the outer perimeter, the second peripheral sidewall enclosure having an outer edge facing the open front;
a planar covering disposed inside the second peripheral sidewall enclosure and hingedly attached to the inner lip, wherein the planar covering extends over the front opening and rests flush along the surface of the inner lip when in a closed position such that the interior volume is fully enclosed;
an outer frame having a planer front surface and an orthogonal lip along the inner perimeter and slots disposed at regular intervals about the, the lip being configured to fit inside the second peripheral sidewall, wherein the slots are configured to receive the tabs therein.

2) The housing for alarm system electrical equipment of claim 1, wherein the rear wall has a space configured to receive an electrical circuit board thereon.

3) The housing for alarm system electrical equipment of claim 1, wherein a plurality of planar flanges extend orthogonally outward from the peripheral sidewalls

4) The housing for alarm system electrical equipment of claim 1, wherein apertures for receiving fasteners are disposed at regular intervals along the length of the outer flanges.

5) The housing for alarm system electrical equipment of claim 1, wherein the rear wall and the peripheral sidewalls have perforated knock-out sections thereon.

6) The housing for alarm system electrical equipment of claim 1, wherein tie-ins for electrical wiring are disposed on an interior of the rear wall and the peripheral sidewalls.

7) The housing for alarm system electrical equipment of claim 1, wherein the planar covering includes a locking mechanism configured to retain the planar covering in a closed position when actuated.
